(19) United States
(12) Patent Application Publication
(10) Pub. No.: US 2004/0209431 A1
(43) Pub. Date: Oct. 21, 2004

(54) Semiconductor memory device and method of manufacturing the same

(75) Inventors: Kiyonori Oyu, Tokyo (JP); Atsushi Ogishima, Tokyo (JP); Hiroyuki Uchiyama, Tokyo (JP); Keizo Kawakita, Tokyo (JP); Masahito Suzuki, Kodaira-shi (JP)

Correspondence Address: OSTROLENK FABER GERB & SOFFEN, 1180 AVENUE OF THE AMERICAS, NEW YORK, NY, 100368403

(73) Assignee: Elpida Memory, Inc.

(21) Appl. No.: 10/626,095

(22) Filed: Jul. 24, 2003

(30) Foreign Application Priority Data
Jul. 25, 2002 (JP) 2002-216112

(51) Int. Cl. H01L 21/336

(52) U.S. Cl. 438/301

(57) ABSTRACT

An active region 1 has diffusion layers 6a to 8a sandwiched by plural word-lines. The diffusion layer 6a sandwiched by word-lines 2 and 3 locates at a center of the active region 1 and connects to a bit-line through a contact. The diffusion layers 7a and 8a sandwiched by word-lines 2 and 3 and both sides of the active region 1 respectively are connected to capacitor portions. A cell structure is formed of two cell transistors. One cell transistor has the word-line 2 as a gate and the diffusion layers 6a and 7a as source and drain, respectively. The other cell transistor has the word-line 3 as a gate and the diffusion layers 6a and 8a as a source and a drain, respectively. The diffusion layers 7a and 8a placed outside of the active region 1 are n-type and have high carrier concentration of n-type at the region separated from word-lines than to the region close to the word-lines 2 and 3. A p-type substrate exhibits low concentration at the region outside the word-lines. As a results, it is possible to prevent the deterioration of refresh characteristic suffering from the adjacent word-line of the adjacent cell and to reduce fraction defective after packaging and reflowing processes.

### BACKGROUND OF THE INVENTION

The present invention relates to a semiconductor memory device having a cell portion which includes two cell transistors and to a method of manufacturing the same. The two cell transistors comprises a center diffusion layer which is sandwiched between two word lines and which is connected to a bit line through a contact and diffusion layers each of which is arranged on a side adjacent to the center diffusion layer and each of which is connected to the capacitor portion through a contact. Especially, in a dynamic random access memory (DRAM) with a high density, the present invention relates to a semiconductor device and a manufacturing method thereof which achieves an improved refresh characteristic and which reduces the defective fraction in the process after the completion of packaging step and mounting, soldering and reflowing steps.

With the advance of the recent technology, an STI (Shallow Trench Isolation) technology has been utilized in the existing semiconductor memory device so as to reduce the spaces between the bit-lines for a device, for example, exhibiting 256 megabits realized by 0.15 μm process. Furthermore, it is anticipated that, a device of 16 gigabits will be realized in the near future by the use of the STI technology joined with the other technologies.

Referring to FIG. 1, description will be at first made about a cell portion of the DRAM as one of the semiconductor memory devices.

FIG. 1 illustrates a plan view of the cell portion of the DRAM which has an active region 1 and word-lines 2 to 5. The word-lines 2 to 5 are provided in order of word-lines 4, 2, 3, and 5 and are arranged in parallel to each other. The active region 1 has diffusion layers 7, 6, and 8 sandwiched by the regions formed between the word-lines 4, 2, 3, and 5 respectively.

The diffusion layer 6 sandwiched between word-lines 2 and 3 is connected with a bit-line through a contact. The diffusion layer 7 sandwiched between word-lines 2 and 4 and the diffusion layer 8 sandwiched between word-lines 3 and 5 are connected with capacitor portions through contacts. The cell portion includes two transistors. One of the transistors has the word-line 2 as a gate electrode and the diffusion layers 6 and 7 as a source and a drain, respectively. Another transistor has the word-line 3 as a gate electrode and the diffusion layers 6 and 8 as a source and a drain, respectively. Further, the diffusion layer 6 is used commonly as the source-drain of the above-mentioned two transistors and is connected with a bit-line.

At first referring to FIG. 1 and FIG. 2, description will be made about a carrier concentration distribution on a surface of the conventional active region 1. Referring to FIG. 2 showing the conventional carrier concentration distribution, an n-type carrier concentration in each of the regions 6a to 8a corresponding to the n-type diffusion layers 6 to 8 respectively is equal on both sides standing adjacent to the word-lines.

Such concentration distribution of the semiconductor memory device is obtained by the conventional method for manufacturing a structure shown in, for example, FIG. 3 and FIG. 4.

Referring to FIG. 3, a shallow trench is formed on a silicon substrate. The shallow trench forms a shallow trench element isolation (hereafter called as STI) layer 9 having an implantation-through film 10 on the bottom of the STI layer 9. Next, boron ion is implanted through the implantation-through film 10 and a p-type well layer 11 is formed in the silicon substrate. By the boron-ion implantation for controlling of a threshold voltage Vth (BF₂, 45 keV, 1×10¹²/cm²), an n-type diffusion layer or a boron-implanted layer 27 is formed through the implantation-through film 10 inside of the STI layer 9. The boron ion implantation is carried out for the entire surface of the active region. The state is shown in FIG. 3.

Next referring to FIG. 1, a gate oxide film 15 is formed on the STI layer 9 including the implantation-through film 10. Then a gate electrode comprising W/WN (tungsten/tungsten nitride) film 16 and a poly-crystal silicon layer 17 is formed. A SiN (silicon nitride) film 18 is deposited on the W/WN film 16 and disposed by a patterning thereon. The gate electrode is formed by patterning the W/WN film 16 and the poly-crystal silicon layer 17 with mask of the patterned SiN film 18. After forming the gate electrode, thermal oxidation is carried out in hydrogen atmosphere containing (water) vapor so as to oxidize the side-wall of the poly-crystal silicon layer 17 and the substrate surface of the boron-implanted layer 27 which is an n-type diffusion layer.

Next, phosphorus is implanted through the exposure portion of the implantation-through film 10 under the condition of 10 keV and 2×10¹²/cm², and a low-concentration n-type layer 190 is formed as a source and a drain of a cell transistor. FIG. 4 shows the structure of this state. Herein, the carrier concentration distribution shown in FIG. 2 is realized.

The above-mentioned semiconductor memory device and the manufacturing method thereof have the following problems.

The first problem is that the refresh characteristic is deteriorated because of the influence of the adjacent word-line in the carrier concentration distribution of the active region surface. In 256 megabit products produced by 0.15 μm processing, for example, there is a problem of a reflowing deterioration affected by the adjacent word-line. As a feature of the reflowing deterioration bits, the refresh characteristic is deteriorated when the silicon surface in vicinity of the adjacent word-line is depleted, and the refresh characteristic restores when the silicon surface is in the reversed state. At present, as no limitation is provided for the depletion or the restoration of the substrate surface, the refresh characteristic may be deteriorated by the depletion of silicon surface in vicinity of the adjacent word-line.

Referring to FIG. 5 for example, description will be made about the case in which an adjacent word-line 5 is overlapped on the active region. In this case, due to the deviation occurred during the lithography processing, the undesirably strong electric field occurs in the region 8a of the n-type diffusion layer 8 shown in FIG. 2. Specifically, the strong electric field in the end portion of the region 3a of the word-line 3 is added to the strong portion of electric field in the end portion of the region of the adjacent word-line 5. As a consequence, two strong electric field portions appear in the carrier concentration distribution of the surface of the active region. Thus the characteristic is deteriorated twice as much worse.

The second problem is that the fraction defective rate increases after packaging or reflowing. Referring to FIG. 6, this problem occurs because the electric field has the maximum value thereof according to the position of the adjacent word-line. The position of the adjacent word-line is decided by the change of size in the STI layer forming process and by displacement in the lithography process of the word-line forming. Referring to FIG. 5, as the side of the adjacent word-line 5 is positioned close to the side-wall of the STI layer 9, there is an influence of compression power from the boundary of the STI layer 9. As the band-gap in silicon crystal of the poly crystal silicon film 17 become narrowed due to the compression power, the electric field works as if the electric field became larger corresponding to the generation of the carriers of a small number. The refresh characteristic is deteriorated due to the increase of the conjunction electric field. The refresh characteristic is also deteriorated due to the increase of the compression power. The compression power moreover increases during the process of packaging or reflowing such that the refresh characteristic will correspondingly be deteriorated.

### SUMMARY OF THE INVENTION

In order to solve the above-mentioned problems, it is an object of the present invention to provide a semiconductor memory device and manufacturing method thereof for preventing the occurrence of deterioration of the refresh characteristic and prevent the affect of the adjacent word-line. According to the present invention, it is possible to improve the refresh characteristic and to reduce the fraction defective which may be occurred after packaging and after reflowing processing.

According to an aspect of the present invention, in a cell structure of the semiconductor memory device, a silicon surface positioned near an adjacent word-line is always in a reverse condition, i.e. always being an n-type, regardless of electric potential of the adjacent word-line. This prevents a fluctuation of a refresh characteristic suffering from effect of electric potential of the adjacent word-line. Specifically, an n-type diffusion layer in which the word-lines of in adjacent cell and the word lines of an own cell are positioned adjacent to each other in a cell transistor has an n-type carrier concentration which is higher at the side close to the word-line of the adjacent cell than at the side close to the word-line of the own cell, or the p-type substrate has a p-type carrier concentration which is lower at the side close to the word-line of the adjacent cell than at the side close to the word-line of the own cell. The present invention also realizes a high concentration for the STI side-wall channel which causes the reduction of a threshold voltage Vth of the cell transistor.

According to the present invention, substrate concentration can be prevented from being high to cause the unnecessarily high density and the refresh characteristic can be improved. In other words, it is possible to prevent deterioration of the refresh characteristic suffered from an effect of an adjacent word-line in an adjacent cell. As the result, it is possible to improve an ability of the refresh characteristic and to reduce any fraction defective after packaging and after reflowing.

A semiconductor memory device according to the present invention is embodied by the manufacturing method described below. The method is a manufacturing method of the semiconductor memory device structured by cell transistors. The method includes the following two processes which are carried out before the gate oxidizing process.

One of the above-mentioned processing is that an ion-implantation is carried out to implant, by the use of the mask, phosphorus or arsenic into an active region at a side close to an adjacent word-line in an n-type diffusion layer. Herein, the n-type diffusion layer is formed by the word-line of an adjacent cell and the word line of an own cell positioned adjacent to each other.

Another processing is that ion implantation is carried out to implant, by the use of the mask, phosphorus or arsenic into an active region at the position except where an adjacent word-line of an adjacent cell does not exist. Herein, the n-type diffusion layer is formed by the word-line of an adjacent cell and the word line of an own cell positioned adjacent to each other.

According to another aspect of the present invention, a shallow trench forming process by STI (Shallow Trench Isolation) by the use of the mask is carried out and, following to the shallow trench forming process, the below-mentioned processes are succedingly carried out. One of the processes is that ion-implantation is carried out to implant phosphorus or arsenic to the active region except for the STI region. Herein, the implantation is performed from the position parallel to the longitudinal direction of the active region and take an oblique direction toward the STI side wall. By performing this process, the ion-implantation region on the bottom portion of the STI Shallow Trench is eliminated. Another process is that ion-implantation is carried out to implant phosphorus or arsenic to the active region except for the STI region and the implantation is performed from the position parallel to the longitudinal direction of the active region and toward the STI side wall with a predetermined angle of rotation to the implantation. Yet another process is that ion-implantation is performed to implant ion of boron toward side-wall of STI with a predetermined rotation and taking oblique direction from vertical direction to longitudinal direction of active region except for the STI region.

### BRIEF DESCRIPTION OF THE DRAWINGS

FIG. 1 is a plan view of an active region and word-lines in a cell portion of memory device;

FIG. 2 is a sample graph of an existing carrier concentration distribution of a surface of an active region;

FIG. 3 is a cross-sectional view for showing a state after the completion of a process of forming a bore implantation layer in a cell portion;

FIG. 4 is a cross-sectional view for showing a state subsequent to the process shown in FIG. 3, which is after the completion of a process of forming a low concentration n-type layer;

FIG. 5 is a cross-sectional view for showing a state subsequent to the process shown in FIG. 2, which is an occurrence of deviation on a part of word-lines after forming a low concentration n-type layer;

FIG. 6 is a graph showing changes of junction electrode field according to the overlapping condition of adjacent word-line and active region based on an existing manufacturing method;

FIG. 7 is a sample graph slowing a carrier concentration distribution of a surface of an active region according to an embodiment of the present invention;

FIG. 8 is a sample graph according to an embodiment of a carrier concentration distribution of phosphorus or arsenic of a surface of an active region according to an embodiment of the present invention;

FIG. 9 is a cross-sectional view for showing a state after completion of forming process of a threshold voltage control layer in cell portion;

FIG. 10 is a cross-sectional view for showing a state subsequent to a process shown in FIG. 9, which is a state after completion of forming a phosphorus-implanted layer by the use of a resist mask in the cell portion;

FIG. 11 is a cross-sectional view for showing a state subsequent to a process shown in FIG. 9, which is a state after forming a low concentration n-type layer in the cell portion;

FIG. 12 is a sample graph of a carrier concentration distribution of boron of a surface of an active region according to an embodiment of the present invention;

FIG. 13 is a cross-sectional view for showing a state after completion of a process of forming a boron-implanted layer in the cell portion which is carried out using a method different from the method shown in FIGS. 9 to 11;

FIG. 14 is a cross-sectional view for showing a state subsequent to a process shown in FIG. 13, a state which is after completion of a forming process of a low concentration n-type layer in the cell portion;

FIG. 15 is a plane view of an active region and word-lines in a cell portion of memory device different from FIG. 1;

FIG. 16 is a cross-sectional view for showing a method according to the present invention for rendering an n-type carrier concentration of STI trench-side wall channel of the cell portion become high;

FIG. 17 is a plan view of an active region and word-lines in a cell portion of memory device different from FIG. 15;

FIG. 18 is a cross-sectional view for showing a method according to the present invention and which is different from that shown in FIG. 16, for rendering an n-type carrier concentration of STI trench-side wall channel of the cell portion become high;

FIG. 19 is a cross-sectional view for showing a method according to the present invention and which is different from those shown above, for rendering an n-type carrier concentration of STI trench-side wall channel of the cell portion become high; and

FIG. 20 is a cross-sectional view for showing a method according to the present invention for rendering a p-type carrier concentration of STI trench-side wall channel of the cell portion become high.

### DESCRIPTION OF THE PREFERRED EMBODIMENTS

Description will be made in detail for the embodiments according to the present invention with reference to the accompanying drawings.

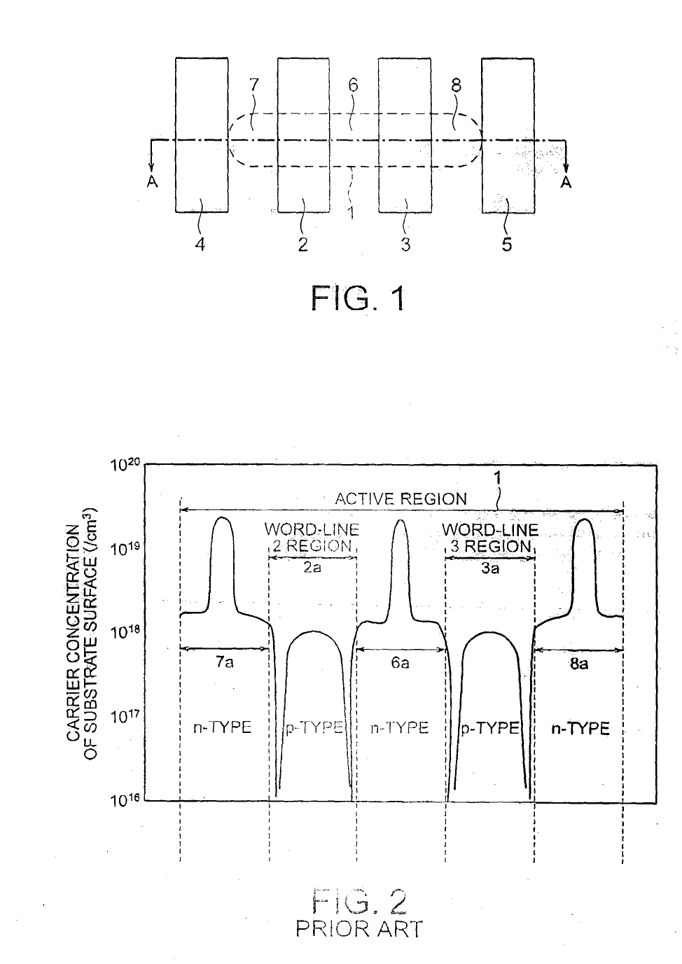

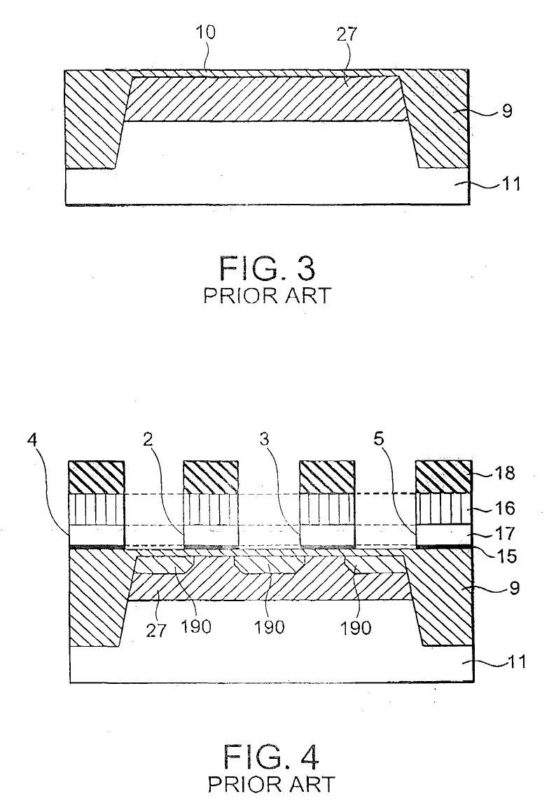

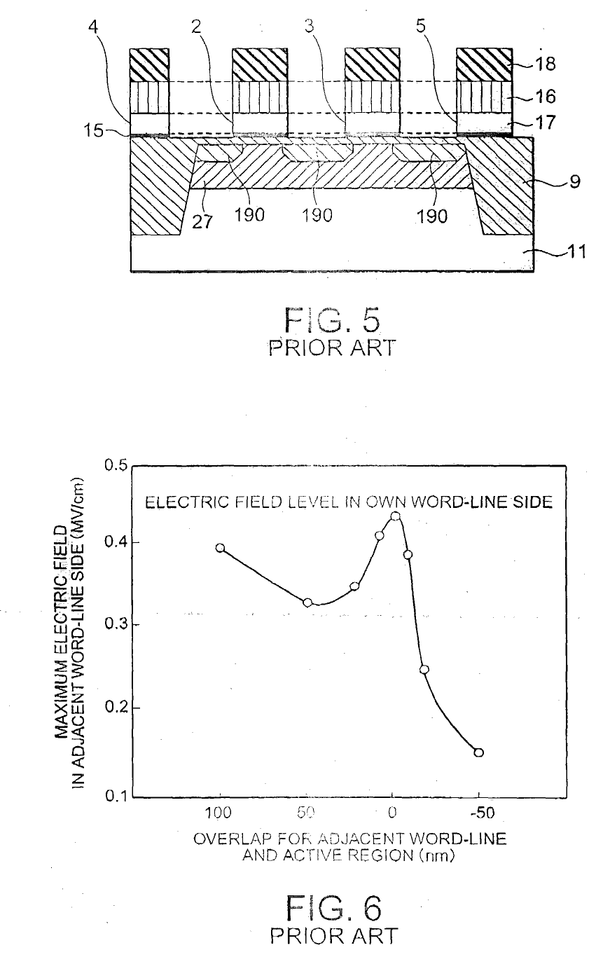

Referring to FIG. 1, description will made about a semiconductor device according to the first embodiment of the present invention. FIG. 1 shows an active region 1 and word-lines 2 to 5.

The word-lines 2 to 5 are positioned in parallel and in the order of the line 4, 2, 3, and 5. The active region 1 has diffusion layers 7, 6, and 8, each of which is sandwiched between the word-lines 4, 2, 3, and 5, respectively. The diffusion layer 6 between the word-lines 2 and 3 is connected to a bit-line through a contact. The diffusion layer 7 between the word-lines 2 and 4 is connected to a capacitor portion through a contact while the diffusion layer 8 between the word-lines 3 and 5 is connected to another capacitor portion through a contact. In this case, a cell portion comprises two cell transistors. One transistor has the word-line 2 as a gate electrode and the diffusion layers 6 and 7 as a source and a drain, respectively. The other one has the word-line 3 as a gate electrode and the diffusion layers 6 and 8 as a source and a drain, respectively. Accordingly, the diffusion layer 6 is commonly used for the source and the drain of the two transistors and connected to a bit-line.

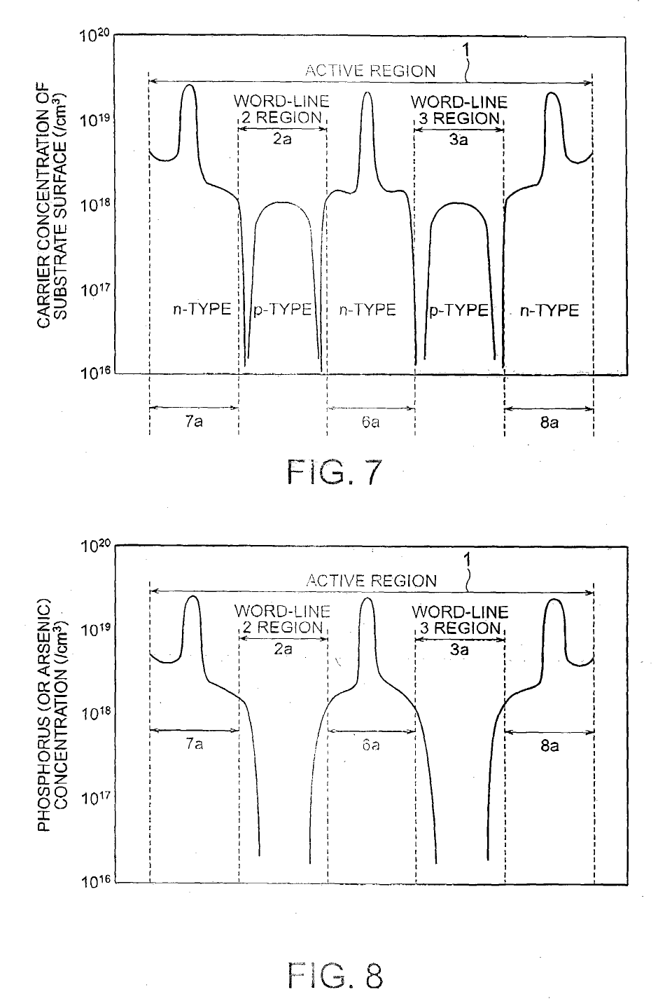

Referring to FIG. 7 together with FIG. 1, description will be made about a carrier concentration distribution state of substrate surface of the active region 1 in the semiconductor memory device according to the present invention. FIG. 7 shows a carrier concentration distribution in a substrate surface of an active region 1 taken along a line A-A in FIG. 1.

The regions 2a and 3a for the word-lines 2 and 3, respectively, are p-type layers having the concentration of about 1×10¹²/cm². A threshold voltage of a MOS transistor is determined by a gate electrode of the word-lines 2 and 3. The region 6a between the word-lines 2 and 3 is an n-type layer having the concentration of about 1×10¹²/cm². The concentration of the contact portion to be connected to the bit-line is raised high by the phosphorus diffusion from poly-crystal silicon used of a contact plug.

The region 7a between the word-lines 2 and 4 is an n-type layer and has high concentration at the side close to the adjacent word-line 4 than at the side close to the own word-line 2. In the same way, the region 8a between the word-lines 3 and 5 is also an n-type layer and also has high concentration at the side close to the adjacent word-line 5 than at the side close to the own word-line 3. For example, the concentration of the sides near the own word-lines 2 and 3 of is 1.5×10¹²/cm² while the concentration of the sides near the adjacent word-lines 2 and 3 is 3×10¹²cm². The concentration of the contact portion connected to the capacitor portion is raised high by phosphorus implantation from poly-crystal silicon of a contact plug.

As the result, even if the adjacent word-line 4 or 5 is overlapped on the active region 1 due to the deviation of lithography, the n-type layer in each of the regions 7a and 8a of near sides of the adjacent word-lines 4 and 5 will not be depleted.

Following methods are used for the purpose of realizing the carrier concentration distribution shown in FIG. 7, i.e. to realize high concentration at the side near the adjacent word-lines 4 and 5 of the regions 7a and 8a corresponding to the n-type diffusion layers 7 and 8 of the cell transistor.

The first method is that ion-implantation of phosphorus or arsenic is carried out for the side near the adjacent word-lines 4 and 5 before or after ion-implantation process of boron for the threshold voltage control. As the result, the n-type impurity concentration distribution by phosphorus or arsenic is obtained as shown in FIG. 8.

Referring to FIGS. 9 to 11 together with FIGS. 1 and 7, description will be made about a first method.

Referring to FIG. 9, the first process is forming an STI layer 9 providing with a shallow trench so as to make side-walls and an implantation through film 10 of the bottom into a silicon substrate. Then ion-implantation of boron through the implantation through film 10 is executed and a p-type well layer 11 is formed. Next, ion-implantation of boron for threshold-voltage control under conditions of BF₂, 45 keV, and 1×10¹²/cm², a threshold voltage control layer 12 is formed, And a state of FIG. 9 shows low concentration of n-type impurity appears.

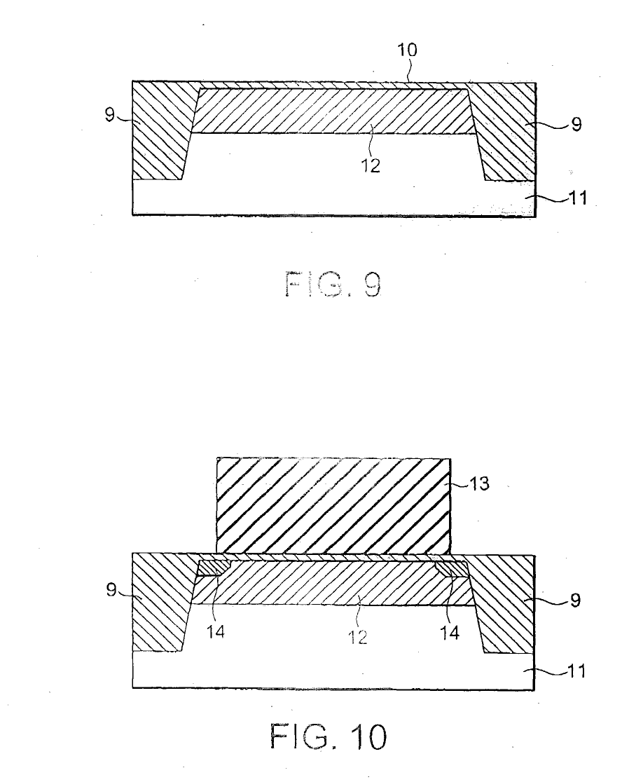

Referring to FIG. 10, the next process is forming a resist mask 13 placed inner side position than the shallow trench side-walls of the STI layer 9 and on the implantation-through film 10 of the STI layer 9. That is, the resist mask 13 is formed in the active region near the adjacent word-lines and taking a space for ion-implantation of phosphorus. Then, a phosphorus-implanted layer 14 is formed by the use of the resist mask 13, ion-implantation of phosphorus by 10 keV and 3×10¹²/cm² into the active region near the adjacent word-lines formed on the STI layer 9. In the phosphorus implantation, there is a risk of reduction of the threshold voltage due to the heat treatment which is performed in the subsequent process. In order to avoid the risk, arsenic implantation process is carried out under the condition of 20 keV and 1×10¹²/cm².

Referring to FIG. 11, the next process is forming a gate oxide film 15 on the surface of the STI layer 9 including the implantation-through film 10. Thereafter a gate electrode layer composed of a W/WN film 16 and a poly-crystal silicon 17 is formed. After patterning SiN film 18 on the W/WN film 16, the gate electrode is formed by patterning the W/WN film 16 and the poly-crystal silicon using SiN film 18 as a mask. Then the thermal oxidation is carried out in a hydrogen atmosphere with water vapor. The substrate surface forming side-walls of the poly-crystal silicon 17 and portion of the n-type diffusion layer is oxidized. Then ion-implantation of phosphorus under condition of 20 keV and 2×10¹²/cm² is carried out for forming a low concentration n-type layer 19 as a source and a drain of the cell transistor.

The following processes of manufacturing DRAM are substantially similar to the usual DRAM manufacturing processes. Therefore the descriptions therefore are omitted.

A dose quantity obtained by implantation of phosphorus is 2×10¹²/cm² for the low concentration n-type at the portion near the own word-lines 2 and 3 and 2×10¹²/cm² for the phosphorus-implanted layer 19 at the portion near the adjacent word-line. As the result, the concentration distribution shown in FIG. 8 is achieved.

The second method for realizing the carrier concentration distribution shown in FIG. 7 is that the p-type substrate concentration of the cell transistor is lowered at the portion close to the adjacent word-line.

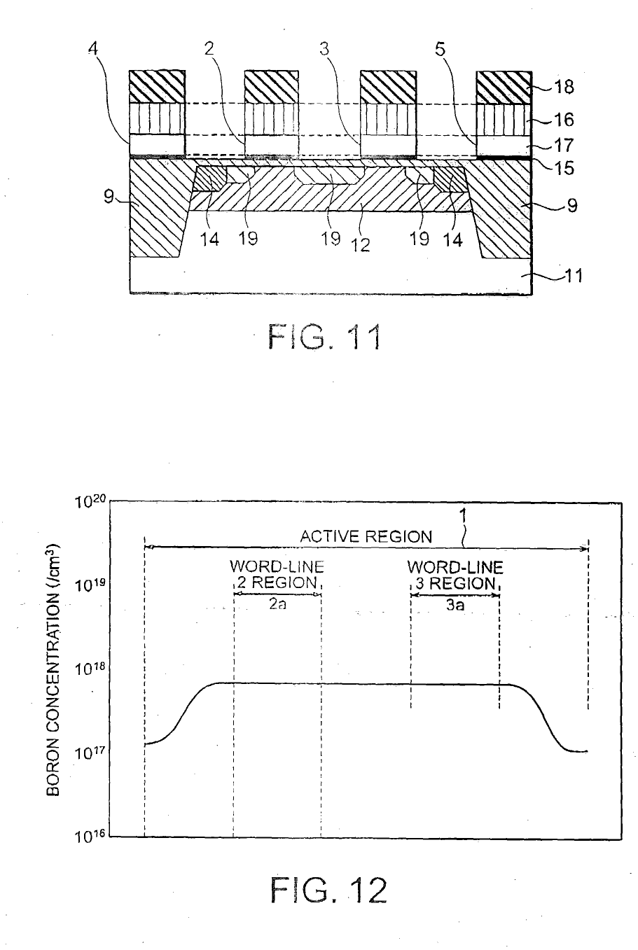

As shown in FIG. 13, the ion-implantation of boron for control of threshold voltage of the cell transistor is not carried out to the side of the adjacent word-line. By this method, the boron concentration distribution as shown in FIG. 12 is obtained.

Referring to FIGS. 12 to 14 and FIGS. 1 and 7, the second method will be described hereinbelow.

For obtaining the boron concentration distribution as shown in FIG. 12, p-type well layer 11 is formed as shown in FIG. 9 as same as the above the first method.

Referring to FIG. 13, the boron ion implantation of BF₂, 45 keV, and 1×10¹²/cm² for controlling the threshold voltage is carried out. Herein, by the use of the resist mask 13a, the ion implantation is not carried out for the portion near the adjacent word-line formed on the STI Layer 9. For this purpose, the resist mask 13a has a boron ion implantation region inside the shallow trench at the bottom of the STI layer 9. A space is left between a boron implantation layer 20 formed by implanting of boron ion into such region and the shallow trench side-wall of the STI layer 9 as shown in FIG. 13.

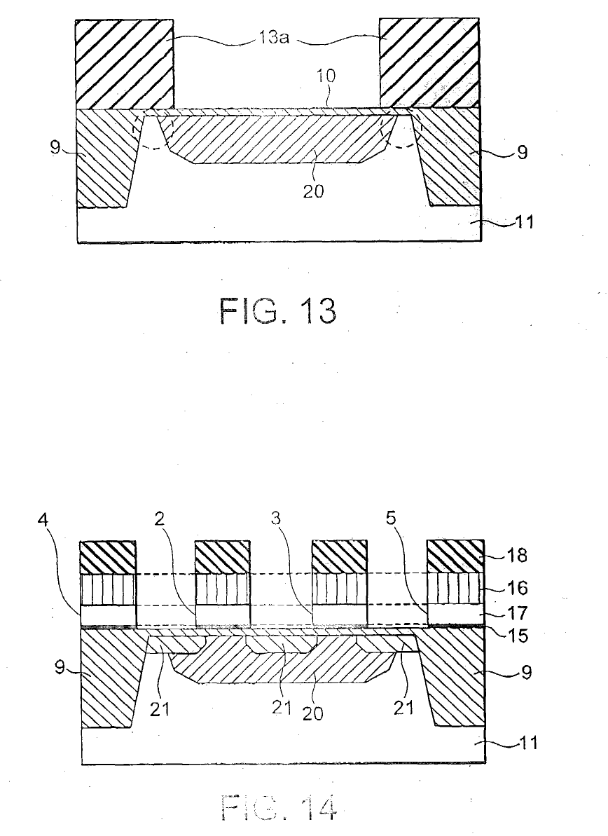

Description proceeds with reference to FIG. 14. After forming the boron implantation layer 20, a gate oxide film 15 is formed on the surface of the implantation-through film 10 of the STI layer 9. Then a gate electrode layer having a W/WN film 16 and a poly-crystal silicon film 17 is formed. A gate electrode is formed by patterning the SiN film 18 on the W/WN film 16 and then patterning the W/WN film 16 and the poly-crystal silicon film 17 by using the SiN film 18 as the mask. After the gate electrode is formed, a thermal oxidation is carried out in the hydrogen atmosphere containing water vapor so as to oxidize the side-wall of the poly-crystal silicon film 17 and the substrate surface of the n-type diffusion layer. Next, phosphorus ion implantation (10 keV and 2×10¹³/cm²) is carried out for forming a low concentration n-type layer 21 which will become a source and a drain of the cell transistor as shown in FIG. 14.

Although the description has individually been made for the first and the second methods, it is possible to combine both methods.

As the carrier concentration distribution of the active region surface as shown in FIG. 7 can be realized, the occurrence of the depletion can be avoided even if the adjacent word-line is positioned on the active region shown in FIG. 1 with the overlapping portion. Moreover, the refresh characteristic will not be suffered from the influence of the adjacent word-line potential. The capability of the refresh characteristic is determined by junction electric fields of both the own word-line end and the adjacent word-line end. Therefore, in case where the affect of the adjacent word-line end is prevented, the capability of the characteristic is improved accordingly.

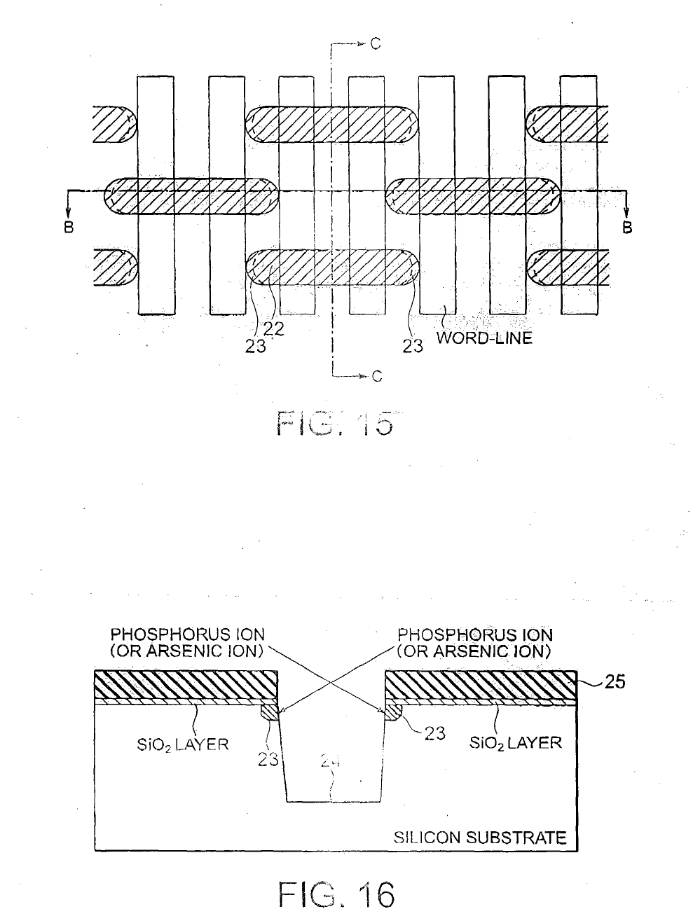

Next, referring to FIGS. 15 to 20, description will be made about a semiconductor memory device according to the second embodiment of the present invention for achieving the concentration distribution for phosphorus or arsenic shown in FIG. 8.

Referring to FIG. 15, directly after the shallow trench for the STI (Shallow Trench Isolation) has been formed, an ion-implantation of phosphorus or arsenic is carried out Herein, phosphorus or arsenic is implanted in parallel and in a longitudinal direction along the active region 22 except for the STI region so as to form the phosphor- or arsenic-implanted layer 23 at the longitudinal end portion of the active region 22.

Next referring to FIG. 16, description will be made about the process of forming the above-mentioned implantation layer 23.

As shown in FIG. 16, STI trench 24 is formed and thereafter the ion-implantation of phosphorus is carried out through the SiN mask 25. In this process, the ion-implantation should be carried out so as to make the depth of the implantation about 50 nm. FIG. 16 is a view of the section taken along a line B-B shown in FIG. 15. In this section, the width of the STI trench is 450 nm and the film thickness of the SiN mask 25 is about 120 nm. Consequently the implantation angle θ is 15 degree. The ion-implantation condition is 5 keV and 3×10¹³/cm² in case of phosphorus while the condition is 10 keV and 2×10¹³/cm² in case of arsenic.

During this process, ion of phosphorus or arsenic is hardly implanted to the short hand direction of the active region 22 shown in FIG. 15. This is because most of the ion will be reflected when ion are emitted with a small angle toward the Si side wall. During the later processes, seed of the ion implantation will be re-distributed by the steps of a liner oxidation of the side wall of the STI trench wall, densifying after burying the trench, annealing after the well implantation, gate oxidation, and the like. The concentration in vicinity of the substrate surface is reduced. The setup of the amount of the ion irradiation is controlled taking the reduction of the concentration in consideration.

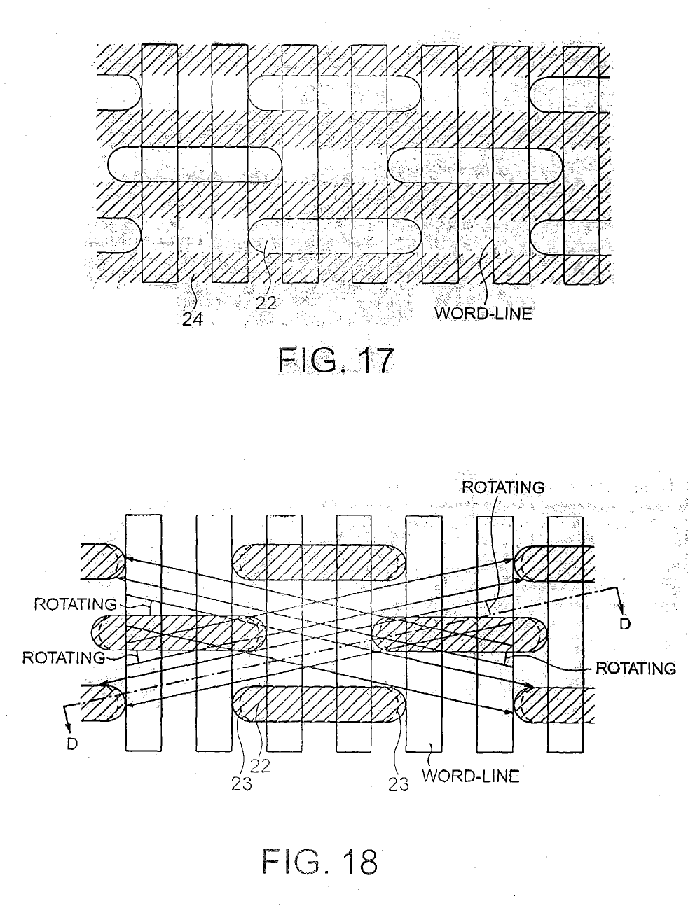

The above-described ion-implantation is carried out so as to implant the ion into the bottom portions (shaded portion illustrated in FIG. 17) of the STI trench 24. Therefore, after the ion implantation, a process should be performed to make the trench deeper in order to remove the ion-planted portions. In case where the ion-implanted portions could not be completely removed, they may be implied into the oxide film by a liner oxidation.

Next referring to FIG. 18, description will be made about a method for carrying out an ion-implantation except for the bottom portion of the STI trench 24 shown in FIG. 17. In order to carry out the implantation to the desired region and to avoid the specific region, the implantation direction should be rotated and changed. In FIG. 18 for example, an implantation angle is rotated for about 8 degrees with respect to a longitudinal direction of the active region 22.

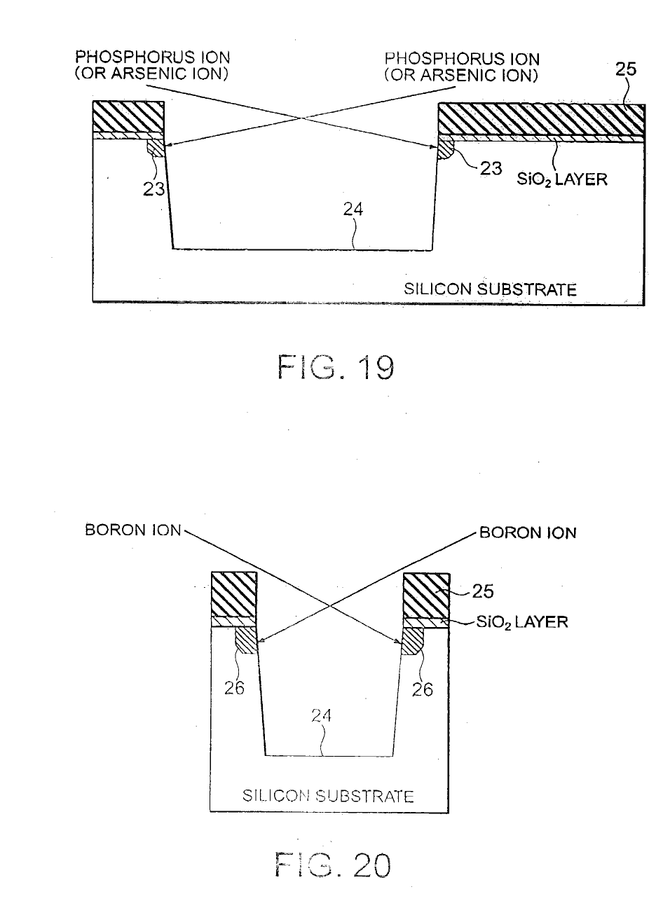

FIG. 19 shows a sectional view taken along a line D-D in FIG. 18. In FIG. 19, 5 degree is selected as the ion implantation angle so as to achieve the implantation depth of about 50 nm through the SiN mask 25 of the implantation mask. Herein, the ion-implantation process with a rotated angle is carried out for four times. The amount of irradiation for phosphorus implantation at each rotation is given by 7.5×10¹²/cm² while the amount of irradiation for arsenic implantation at each rotation is given by 5×10¹²/cm².

Next, FIG. 20 shows a sectional view taken along a line C-C shown in FIG. 15. A boron implantation layer 26 is formed by a boron ion-implantation which is emitted in a direction vertical to the longitudinal direction of the active region 22 and toward the side-wall of the STI trench 24 taking an oblique line. As the result, the boron concentration distribution as shown in FIG. 12 can be achieved.

As shown in FIG. 20, an angle for the oblique ion-implantation of boron through the SiN mask is selected so as to make the depth of implantation about 50 nm. In the sectional view shown in FIG. 20, the STI trench 24 has a width of about 450 nm and the SiN mask 25 has a thickness of about 120 nm. In this case, the implantation angle θ is fixed to 15 degrees. The condition of the boron ion implantation is set up as 10 keV and 1×10¹³/cm². At this time, the ion-implantation will not be carried out for the end portions in the longitudinal direction of the active region 22.

An advantage of carrying out the above described boron implantation is that, even in the case where the amount of radiation of the ion implantation for controlling the threshold-voltage is reduced to 7×10¹²/cm², it is possible to obtain the threshold voltage substantially equal to that described in the foregoing embodiments. The radiation quantity may be adjusted by raising the energy of the boron oblique implantation so as to further reduce the radiation quantity of the implantation for controlling the threshold-voltage. Moreover, if the condition allows, it is possible to omit the implantation process for controlling the threshold-voltage of the cell transistor.

As described above, after the completion of the implantation process, the STI trench is formed by the use of the normal process. Thereafter the processes as shown in FIGS. 9 through 11 are carried out to manufacture the cell transistor. The advantage of carrying out the above-described boron ion-implantation process is that the threshold voltage substantially equal to that described in the first embodiment can be achieved even if the amount of the radiation of the ion implantation for controlling the threshold voltage is reduced to 7×10¹²/cm². Description of subsequent processes will be omitted because the usual manufacturing processes for DRAM are carried out.

It is possible to carry out the both ion-implantation processes, one of which is a phosphorus or an arsenic ion-implantation to the both end portions of the active region 22, the another is a boron ion-implantation to the active region 22 from the vertical direction.

In the above-described embodiments, in case where the carrier concentration distribution on the active region surface is achieved as shown in FIG. 7, the depletion may not occur even if the adjacent word-line is arranged on the active region. In other words, the adjacent word-line potential will not give any affect. The capability of the refresh characteristic is determined by the junction electric fields of both the own word-line and the adjacent word-line so that the refresh characteristic improves as the influence of the adjacent word line decreases.

Furthermore, when the boron ion implantation is carried out to the active region except for the STI region from the direction vertical to the longitudinal direction and taking an oblique line toward the active region, it is possible to reduce the amount of radiation of the boron ion-implantation for controlling the threshold voltage of the cell transistor and to reduce the junction electric field also.

Description has thus far been made about the structure of the cell transistor of the DRAM, however, it is readily possible for those skilled in the art to put this invention into various other manners. For example, the invention is applicable to other kinds of semiconductor memory device such as the device including the cell structure with high density.

What is claimed is:

1. A semiconductor memory device having a cell-transistor structure in which a word-line of an adjacent cell and a word-line of an own cell are formed adjacent to each other, comprises an n-type diffusion layer having an n-type carrier concentration higher at the region close to the word-line of the own cell than at the region close to the word-line of the adjacent cell.

2. A semiconductor memory device having a cell-transistor structure in which a word-line of an adjacent cell and a word-line of an own cell are formed adjacent to each other comprises an n-type diffusion layer having a n-type impurity concentration obtained by phosphorus or arsenic higher at the region close to the word-line of the own cell than at the region close to the word-line of the adjacent cell.

3. A semiconductor memory device having a cell-transistor structure in which a word-line of an adjacent cell and a word-line of an own cell are formed adjacent to each other, comprises an n-type diffusion layer having a n-type impurity concentration obtained by boron lower at the region close to the word-line of the own cell than at the region close to the word-line of the adjacent cell.

4. A semiconductor memory device having a cell-transistor structure comprising a side-wall channel of an STI (Shallow Trench Isolation) trench with high concentration of boron.

5. A method for manufacturing a semiconductor memory device having a cell-transistor structure, comprising a step of,
preceding to the step of gate oxidation,
carrying out, in an n-type diffusion layer formed of a word line of an adjacent cell and a word line of an own cell, an ion-implantation for implanting phosphorus or arsenic into an active region close to an adjacent word-line of an adjacent cell by the use of a mask.

6. A method for manufacturing a semiconductor memory device having a cell-transistor structure, comprising the steps of:
directly after forming a shallow trench by STI (Shallow Trench Isolation) using an SiN mask;
ion-implanting phosphorus or arsenic from the point parallel to the longitudinal direction of the active region except for the STI region toward an STI side-wall with taking an oblique line, and
removing an ion-implanted region of the bottom portion of the STI shallow trench.

7. A method for manufacturing a semiconductor memory device having a cell-transistor structure, comprising a step of:
directly after forming a shallow trench by STI (Shallow Trench Isolation) using an SiN mask;
ion-implanting, with a rotation at a predetermined angle, phosphorus or arsenic from the point parallel to the longitudinal direction of the active region except for the STI region toward an STI side-wall with taking an oblique line.

8. A method for manufacturing a semiconductor memory device having a cell-transistor structure, comprising a step of,
preceding to the step of gate oxidation,
carrying out, in an n-type diffusion layer formed of a word line of an adjacent cell and a word line of an own cell, an ion-implantation for implanting phosphorus into an active region except for the region close to an adjacent word-line of an adjacent cell by the use of a mask.

9. A method for manufacturing a semiconductor memory device having a cell-transistor structure, comprising a step of:
directly after forming a shallow trench by STI (Shallow Trench Isolation) using an SiN mask;
ion-implanting phosphorus from the point parallel to the longitudinal direction of the active region except for the STI region toward an STI side-wall with taking an oblique line.
